(19) United States
(12) Patent Application Publication
(10) Pub. No.: US 2021/0037644 A1
(43) Pub. Date: Feb. 4, 2021

(54) CIRCUIT BOARD AND LIGHT EMITTING DEVICE PROVIDED WITH SAME

(71) Applicant: KYOCERA Corporation, Kyoto-shi, Kyoto (JP)

(72) Inventor: Yuichi ABE, Satsumasendai-shi, Kagoshima (JP)

(21) Appl. No.: 16/766,951

(22) PCT Filed: Nov. 28, 2018
(86) PCT No.: PCT/JP2018/043817

§ 371 Date: Jul. 22, 2020

(30) Foreign Application Priority Data
Nov. 29, 2017 (JP) 2017-229143

(51) Int. Cl. H05K 1/03; H05K 1/02

(52) U.S. Cl. CPC H05K 1/0306; H05K 2201/0215; H05K 2201/10106; H05K 1/0296

(57) ABSTRACT

A circuit board includes a substrate that is composed of a ceramic and has a first surface, a conductor layer that is based on a metal, and a resin layer that is based on a resin. Each of the conductor layer and the resin layer is located side by side in contact with the first surface. The conductor layer has a first site that covers at least a part of a site of the resin later on a side of the conductor layer and a side of a surface of the resin layer.

### FIELD

The present disclosure relates to a circuit board and a light-emitting device that includes it.

### BACKGROUND

Attention is paid to a light-emitting diode (LED) as a light-emitting element with a less power consumption. Then, a circuit board that includes an insulating substrate and a conductor layer that is located on such a substrate and is provided as a circuit (a wiring) is used for mounting of such a light-emitting element.

Furthermore, improvement of a light emission efficiency is desired for a light-emitting device that is provided by mounting a light-emitting element on a circuit board with a configuration as described above, and in order to improve such a light emission efficiency, covering of a surface of a substrate by a resin with a white-based color tone is executed (see, for example, Patent Literature 1).

### CITATION LIST

### Patent Literature

Patent Literature 1: Japanese Patent Application Publication No. 2009-129801

### SUMMARY

### Technical Problem

A light-emitting element generates heat at a time of an operation thereof. Furthermore, an amount of heat per volume that is applied to a circuit board is increased by downsizing and thinning of such a circuit board in recent years.

In recent years, a ceramic that is excellent in a mechanic strength to facilitate downsizing and thinning and is excellent in a heat release property is widely employed as a material of a substrate that composes a circuit board.

Herein, a bonding strength between a substrate that is composed of a ceramic and a resin layer is less than a bonding strength between such a substrate and a conductor layer. Hence, like Patent literature 1, in a case where a surface of a substrate is covered by a resin with a white-based color tone to improve a light emission efficiency, and as heating and cooling of a circuit board are repeated by an operation of a light-emitting element, such a resin layer may be released from such a substrate and it may be impossible to withstand use for a long period of time.

The present disclosure is discovered by taking such a circumstance into consideration and aims to provide a circuit board that is capable of withstanding use for a long period of time where a resin layer is not readily released from a substrate even when heating and cooling are repeated, and a light-emitting device that includes such a circuit board.

### Solution to Problem

A circuit board in the present disclosure includes a substrate that is composed of a ceramic and has a first surface, a conductor layer that is based on a metal, and a resin layer that is based on a resin. Then, each of the conductor layer and the resin layer is located side by side in contact with the first surface. Moreover, the conductor layer has a first site that covers at least a part of a site of the resin later on a side of the conductor layer and a side of a surface of the resin layer.

Alternatively, a substrate that is composed of a ceramic and has a first surface, a conductor layer that is based on a metal, and a resin layer that is based on a resin are included. Then, each of the conductor layer and the resin layer is located side by side in contact with the first surface. Furthermore, the resin layer has a second site that protrudes toward a side of the conductor layer on a side of the first surface. Then, the conductor layer covers at least a part of the second site.

Furthermore, a light-emitting device in the present disclosure includes the circuit board as described above, and a light-emitting element that is located on the circuit board.

### Advantageous Effects of Invention

It is possible for a circuit board according to the present disclosure to withstand use for a long period of time where a resin layer is not readily released from a substrate even when heating and cooling are repeated.

Furthermore, it is possible for a light-emitting device according to the present disclosure to maintain a light emission efficiency and be used for a long period of time because a circuit board as described above is included therein.

### BRIEF DESCRIPTION OF DRAWINGS

FIG. 1 is a cross-sectional view that schematically illustrates an example of a surrounding of a light-emitting element in a light-emitting device according to the present disclosure.

FIG. 2 is an enlarged view that illustrates an example of an S part as illustrated in FIG. 1.

FIG. 3 is an enlarged view that illustrates another example of a part that corresponds to an S part as illustrated in FIG. 1.

FIG. 4 is an enlarged view that illustrates an example of a T part as illustrated in FIG. 1.

FIG. 5 is an enlarged view that illustrates another example of a part that corresponds to a T part as illustrated in FIG. 1.

FIG. 6 is an enlarged view that illustrates an example of a U part as illustrated in FIG. 1.

### DESCRIPTION OF EMBODIMENTS

Hereinafter, a circuit board and a light-emitting device according to the present disclosure will be explained with reference to each drawing.

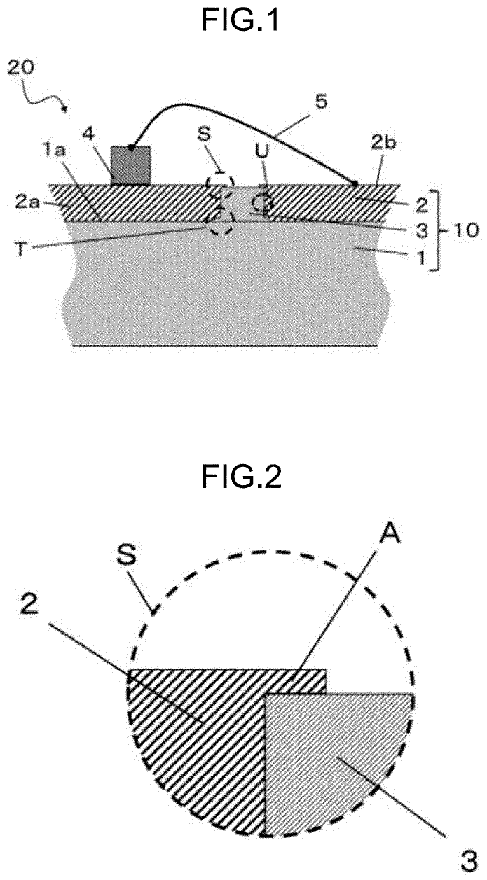

As illustrated in FIG. 1, a circuit board 10 according to the present disclosure includes a substrate 1 that has a first surface 1a, a conductor layer 2, and a resin layer 3, where each of the conductor later 2 and the resin layer 3 is located side by side in contact with the first surface 1a. Additionally, FIG. 1 illustrates an example where the resin layer 3 contacts the conductor layer 2, where this is not limiting and a gap may be present between the conductor layer 2 and the resin layer 3. Furthermore, in FIG. 1, a cross-sectional shape of the conductor layer 2 is a substantially rectangular shape, where this is not limiting and any shape is allowed.

Herein, the substrate 1 in the circuit board 10 according to the present disclosure is composed of a ceramic. For a ceramic, it is possible to provide, for example, an aluminum-oxide-based ceramic, a zirconium-oxide-based ceramic, a composite ceramic of aluminum oxide and zirconium oxide, a silicon-nitride-based ceramic, an aluminum-nitride-based ceramic, a silicon-carbide-based ceramic, a mullite-based ceramic, or the like. Additionally, if the substrate 1 is composed of an aluminum-oxide-based ceramic, it has a mechanical strength that is needed for the substrate 1 and is excellent in processability thereof. Furthermore, if the substrate 1 is composed of an aluminum-nitride-based ceramic, it is excellent in a heat release property thereof.

Herein, for example, an aluminum-oxide-based ceramic contains 70% by mass or more of aluminum oxide among 100% by mass of all components that compose such a ceramic. Then, it is possible to confirm a material of the substrate 1 in the circuit board 10 according to the present disclosure by a following method. First, the substrate 1 is measured by using an X-ray diffractometer (XRD) and identification is executed based on a value of an obtained 2θ (where 2θ is a diffraction angle) by using a JCPDS card. Then, quantitative analysis of a contained component is executed by using an X-ray fluorescence spectrometer (XRF). Then, for example, if presence of aluminum oxide is confirmed by identification as described above and a content provided by converting a content of Al that is measured by an XRF into aluminum oxide (Al₂O₃) equivalent is 70% by mass or greater, it is an aluminum-oxide-based ceramic. Additionally, it is also possible to confirm another ceramic by a method identical thereto.

Furthermore, the conductor layer 2 in the circuit board 10 according to the present disclosure is based on a metal. Herein, being based on a metal refers to a metal that accounts for 50% by mass or greater among 100% by mass of all components that compose the conductor layer 2. Additionally, if a metal is copper or silver, an electrical resistivity is low and a thermal conductivity is high, so that mounting of a light-emitting element 4 with a large amount of heat generation is allowed.

Furthermore, the resin layer 3 in the circuit board 10 according to the present disclosure is based on a resin. Herein, being based on a resin refers to a resin that accounts for 50% by mass or greater among 100% by mass of all components that compose the resin layer 3. Additionally, if a resin is a silicone resin, it is resistant to an ultraviolet ray as compared to another resin that exhibits a white-based color tone (for example, an epoxy resin), so that it is possible to maintain a high reflection efficiency for a long period of time.

Herein, for a confirmation method for a main component that composes the conductor layer 2, for example, it is sufficient that the circuit board 10 is cut so as to provide a cross section as illustrated in FIG. 1 and a cross section that is polished by a cross section polisher (CP) is provided as an observation surface and confirmed by using an energy dispersive X-ray analyzer (EDS) that is attached to and provided on a scanning electron microscope (SEM). Alternatively, it is also possible to chip the conductor layer 2 and execute confirmation by using an ICP optical emission spectrometer (ICP) or an X-ray fluorescence spectrometer (XRF).

On the other hand, for a confirmation method for a main component that composes the resin layer 3, it is sufficient that measurement is executed according to a following method. First, the resin layer 3 is chipped and a rein that is included in the resin layer 3 is specified by using a Fourier transform infrared spectrophotometer (FTIR). Subsequently, the circuit board 10 is cut so as to provide a cross section as illustrated in FIG. 1, and while a cross section that is polished by a CP is provided as an observation surface, the resin layer 3 is measured by an EDS that is attached to and provided on an SEM. In such a measurement, if a total amount of components that compose a resin as described above is greater than a total amount of other components, it is sufficient that such a resin as described above as is regarded as a main component.

Then, as illustrated in FIG. 2, the conductor layer 2 in the circuit board 10 according to the present disclosure has a first site A that covers at least a part of a site of the resin layer 3 on a side of the conductor layer 2 and a side of a surface of the resin layer 3. Herein, a site of the resin layer 3 on a side of the conductor layer 2 and a side of a surface of the resin layer 3 is, in other words, a corner part of the resin layer 3 in a cross section as illustrated in FIG. 2. Furthermore, the first site A is, in other words, a site of the conductor layer 2 that is located on or above the resin layer 3.

A bonding strength between the conductor layer 2 and the substrate 1 is higher than a bonding strength between the resin layer 3 and the substrate 1, so that such a configuration is satisfied and thereby the first site A of the conductor layer 2 serves as supporting the resin layer 3 as the resin layer 3 is nearly released from the substrate 1. Hence, in the circuit board 10 according to the present disclosure, the resin layer 3 is not readily released from the substrate 1 even when heating and cooling are repeated, so that it is possible to withstand use for a long period of time.

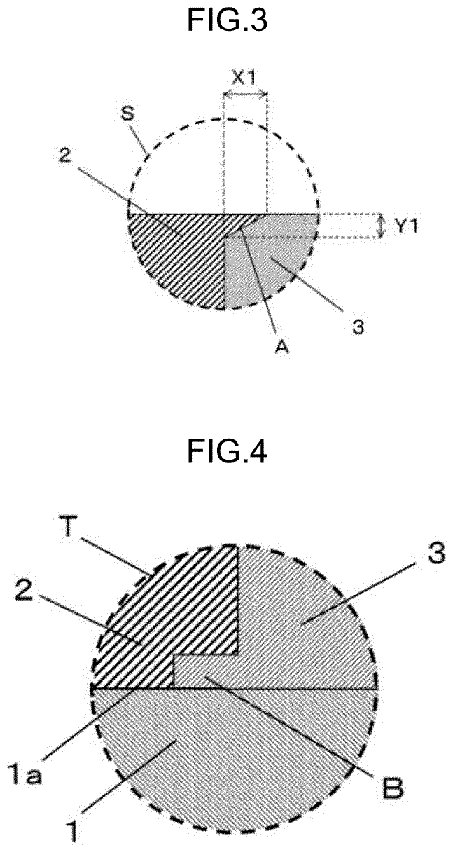

Furthermore, a site that is away from the first surface 1a in the first site A in the circuit board 10 according to the present disclosure may be longer than a site that is close to the first surface 1a, in terms of a length in a direction that is parallel to the first surface 1a. Herein, as stress is applied to the first site A, a crack is readily generated from a root of the first site A, and if such a configuration is satisfied, it is possible to allow stress that is applied to the first site A in the conductor layer 2 to escape from a root of the first site A in a direction of a tip of the first site A. Hence, a possibility of generating a crack in the first site A and thereby chipping is decreased, so that it is possible to maintain bonding between the resin layer 3 and the substrate 1 for a long period of time. Herein, if a configuration is provided in such a manner that a length of the first site A in a direction that is parallel to the first surface 1a is gradually increased with increasing a distance from the first surface 1a as illustrated in FIG. 3, it is possible to allow stress that is applied to the first site A to escape from a root of the first site A in a direction of a tip of the first site A effectively.

Furthermore, in the circuit board 10 according to the present disclosure, as illustrated in FIG. 3, a maximum length X1 of the first site A in a direction that is parallel to the first surface 1a may be 3 μm or greater and 10 μm or less. If such a configuration is satisfied, it is possible to maintain a reflection efficiency of the resin layer 3 and support the resin layer 3 effectively by the first site A.

Furthermore, in the circuit board 10 according to the present disclosure, as illustrated in FIG. 3, a maximum thickness Y1 of the first site A in a direction that is orthogonal to the first surface 1a may be 3 μm or greater and 7 μm or less. If such a configuration is satisfied, it is possible to support the resin layer 3 effectively by the first site A.

Furthermore, in the circuit board 10 according to the present disclosure, as illustrated in FIG. 4, the resin layer 3 has a second site B that protrudes toward a side of the conductor layer 2 on a side of the first surface 1a and the conductor later 2 covers at least a part of the second site B.

As such a configuration is satisfied, the second site B of the resin layer 3 is covered by the conductor layer 2, so that the second site B of the resin layer 3 is not readily released from the substrate 1. Hence, in the circuit board 10 according to the present disclosure, the resin layer 3 is not readily released from the substrate 1 even when heating and cooling are repeated, so that it is possible to withstand use for a long period of time.

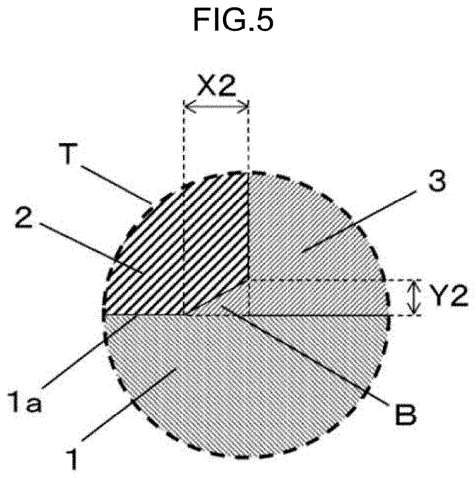

Furthermore, a site that is close to the first surface 1a in the second site B in the circuit board 10 according to the present disclosure may be longer than a site that is away from the first surface 1a, in terms of a length in a direction that is parallel to the first surface 1a. Herein, as stress is applied to the second site B, a crack is readily generated from a root of the second site B, but if such a configuration is satisfied, it is possible to allow stress that is applied to second site B in the resin layer 3 to escape from such a root of the second site B in a direction of a tip of the second site B. Hence, a possibility of generating a crack in the second site B and thereby chipping is decreased, so that it is possible to maintain bonding between the resin layer 3 and the substrate 1 for a long period of time. Herein, if a length of the second site B in a direction that is parallel to the first surface 1a is generally increased with decreasing a distance from the first surface 1a as illustrated in FIG. 5, it is possible to allow stress that is applied to the second site B to escape from a root of the second site B in a direction of a tip of the second site B effectively.

Furthermore, in the circuit board 10 according to the present disclosure, as illustrated in FIG. 5, a maximum length X2 of the second site B in a direction that is parallel to the first surface 1a may be 4 μm or greater and 15 μm or less. If such a configuration is satisfied, a decrease of a bonding strength between the conductor layer 2 and the substrate 1 is reduced by presence of the second site B and a crack is not readily generated in the second site B, so that it is possible to maintain bonding between the resin layer 3 and the substrate 1 for a longer period of time.

Furthermore, in the circuit board 10 according to the present disclosure, as illustrated in FIG. 5, a maximum thickness Y2 of the second site B in a direction that is orthogonal to the first surface 1a may be 3 μm or greater and 10 μm or less. If such a configuration is satisfied, a crack is not readily generated in the second site B, so that it is possible to maintain bonding between the resin layer 3 and the substrate 1 for a longer period of time.

Additionally, in the circuit board 10 according to the present disclosure, if the resin layer 3 has the second site B as described above and the conductor layer 2 has the first site A as described above and covers at least a part of the second site B, it goes without saying that the resin layer 3 is further not readily released from the substrate 1 even when heating and cooling are repeated.

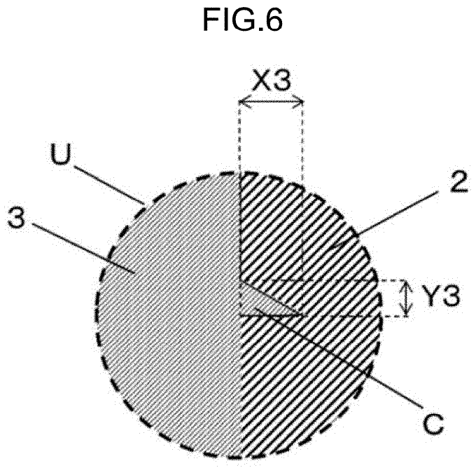

Furthermore, in the circuit board 10 according to the present disclosure, as illustrated in FIG. 6, the resin layer 3 may have a third site C that protrudes toward the conductor layer 2 and the conductor layer 2 may cover at least a part of the third site C.

If such a configuration is satisfied, and as heating and cooling are repeated and the thereby the resin layer 3 is released from the substrate 1, the third site C of the resin layer 3 is pushed by the conductor layer 2, so that the resin layer 3 is not readily released from the substrate 1.

Furthermore, a site that is close to the first surface 1a in the third site C in the circuit board 10 according to the present disclosure may be longer than a site that is away from the first surface 1a, in terms of a length in a direction that is parallel to the first surface 1a. Herein, as stress is applied to the third site C, a crack is readily generated from a root of the third site C, but if such a configuration is satisfied, it is possible to allow stress that is applied to the third site C in the resin layer 3 to escape from a root of the third site C in a direction of a tip of the third site C. Hence, a possibility of generating a crack in the third site C and thereby chipping is decreased, so that it is possible to maintain bonding between the resin layer 3 and the substrate 1 for a longer period of time. Herein, a length of the third site C in a direction that is parallel to the first surface 1a may be gradually increased with decreasing a distance from the first surface 1a as illustrated in FIG. 6. If such a configuration is satisfied, it is possible to allow stress that is applied to the third site C to escape from a root of the third site C in a direction of a tip of the third site C effectively.

Furthermore, as illustrated in FIG. 6, a maximum length X3 of the third site C in a direction that is parallel to the first surface 1a may be, for example, 4 μm or greater and 15 μm or less. Furthermore, a maximum thickness Y3 of the third site C in a direction that is orthogonal to the first surface 1a may be, for example, 3 μm or greater and 10 μm or less.

Furthermore, the resin layer 3 in the circuit board 10 according to the present disclosure contains a metal particle(s) where an equivalent circle diameter(s) thereof is/are 5 μm or less, and as a part of the resin layer 3 that includes a surface in a direction that is away from the substrate 1 is provided as a first region and a part other than the first region is provided as a second region, a number of a metal particle(s) in such a first region is greater than that in such a second region. Herein, a first region of the resin layer 3 is a part from a surface to a depth of 10 μm in a direction that is away from the substrate 1. On the other hand, a second region of the resin layer 3 is a part on a side of the substrate 1 with respect to a part from a surface to a depth of 10 μm in a direction that is away from the substrate 1.

If such a configuration is satisfied, it is possible to maintain a bonding strength between the resin layer 3 and the substrate 1 and release heat that transfers from the conductor layer 2 in a first region that has a lot of metal particles effectively, so that the resin layer 3 is not readily released from the substrate 1. Moreover, it is possible to reflect light of a light-emitting element effectively by a metal particle(s) in a first region of the resin layer 3. Additionally, a metal particle(s) does/do not have to be present in a second region of the resin layer 3.

Herein, a metal particle(s) is/are composed of at least one kind that is selected from copper (Cu), titanium (Ti), and silver (Ag).

Furthermore, a number of a metal particle(s) in a range with a surface area of 1 mm² on a surface of the resin layer 3 in a direction that is away from the substrate 1 may be 2 or greater and 5 or less. If such a configuration is satisfied, it is possible to reflect light of a light-emitting element well by a metal particle(s).

Furthermore, the substrate 1 in the circuit board 10 according to the present disclosure may have a thought-hole(s). Then, if it has an electrode(s) in a through-hole(s) of the substrate 1 and the conductor layer 2 is connected to such an electrode(s), it is possible to supply electricity from an outside to the conductor layer 2 through such an electrode(s). Furthermore, if it has a thermal via(s) with a high thermal conductivity in a through-hole(s) of the substrate 1, it is possible to improve a heat release property of the substrate 1.

Furthermore, as illustrated in FIG. 1, a light-emitting device 20 according to the present disclosure includes the circuit board 10 with a configuration as described above, and the light-emitting element 4 that is located on the circuit board 10. Additionally, FIG. 1 illustrates an example where the light-emitting element 4 is located on a conductor layer 2a and the light-emitting element 4 is electrically connected to a conductor layer 2b by a wire bonding 5. Additionally, although not being illustrated in the drawings, a surface of the light-emitting device 20 on a side where the light-emitting element 4 is mounted may be covered by a sealing material or the like in such a manner that the light-emitting element 4 is included, in order to protect the light-emitting element 4. Additionally, a sealing material may contain a florescent material or the like for wavelength conversion.

Hereinafter, an example of a manufacturing method for a circuit board according to the present disclosure will be explained.

First, a ceramic that has a first surface, such as, for example, an aluminum-nitride-based ceramic or an aluminum-oxide-based ceramic is prepared as a substrate by a publicly known molding method and firing method. Additionally, for fabrication of an aluminum-oxide-based ceramic, barium oxide (BaO), zirconium oxide (ZrO₂), or the like may be contained in order to improve a reflectance of a substrate.

Furthermore, in a case where a through-hole(s) is/are formed in a substrate, it is sufficient that a through-hole(s) as well as an outline shape is/are formed at a time of formation of a molded body, a through-hole(s) is/are formed in a molded body where only an outline shape is processed, by punching, blasting or laser, or a through-hole(s) is/are formed in a sintered body by blasting or laser. Additionally, a thickness of a substrate is, for example, 0.15 mm or greater and 1.5 mm or less.

Then, a conductor layer is formed on a first surface of a substrate. Hereinafter, a case where a conductor layer is composed of titanium and copper will be explained as an example. First, a thin layer of titanium and copper is formed on a first surface of a substrate by sputtering. Herein, for a thin layer, for example, an average film thickness of a thin layer of titanium is 0.03 μm or greater and 0.2 μm or less and an average film thickness of a thin layer of copper is 0.5 μm or greater and 2 μm or less. Then, a resist pattern is formed on a thin layer by photolithography and a new thick layer of copper is formed by using electrolytic copper plating to obtain a conductor layer. Herein, an average film thickness of a thick layer of copper that is formed by electrolytic copper plating is, for example, 40 μm or greater and 100 μm or less.

Then, a resist pattern is eliminated and a protruding thin layer of titanium and copper is eliminated by etching. Herein, a concentration of an etching liquid that is used for etching and a period of time to execute such etching are adjusted appropriately, so that a first surface side of an outer surface of a conductor layer is etched and such a conductor layer is of a shape that has a cut part with any shape at an interface between it and a first surface.

Then, a paste that provides a resin layer (that will be described as a paste for resin layer below) is prepared. A paste for rein layer is provided by, for example, dispersing a silicone resin raw material and a white color inorganic filler powder in an organic solvent.

Herein, for a silicone resin raw material, it is possible to use an organopolysiloxane, an organohydrogenpolysiloxane, a platinum-containing polysiloxane, or the like. Furthermore, for a white color inorganic filler, it is possible to use, titanium oxide, aluminum oxide, zirconium oxide, barium oxide, barium sulfate, or the like. Furthermore, for an organic solvent, it is possible to mix and use one kind or two or more kinds that is/are selected from carbitol, carbitol acetate, terpineol, meta-cresol, dimethylimidazole, dimethylimidazolidinone, dimethylformamide, diacetone alcohol, triethylene glycol, para-xylene, ethyl lactate, and isophorone.

Additionally, for a mass ratio in a paste for resin layer, preparation is executed, for example, so as to provide 0.5 to 4 of a white color inorganic filler and 20 to 100 of an organic solvent, relative to 1 of a silicon resin raw material. Furthermore, in order to contain a metal particle(s) in a resin layer, it is sufficient that a metal particle(s) that is/are composed of at least one kind that is selected from copper, titanium, and silver and provided with an equivalent circle diameter(s) of 5 μm or less is/are added to a paste for resin layer.

Then, a paste for resin layer is printed on a first surface of a substrate so as to be located side by side with a conductor layer. Herein, printing is executed in such a manner that a paste for resin layer penetrates into an inside of a cut part of a conductor layer, so that a resin layer is of a shape that has a second site that protrudes toward a side of such a conductor layer on a side of a first surface.

Additionally, in order that a resin layer has a third site that protrudes toward a conductor layer, it is sufficient that such a conductor layer is fabricated in two batches. Specifically, first, a first thick layer of copper is formed on a thin layer of titanium and copper, and subsequently, a resist pattern is eliminated. Herein, for a thin film, for example, an average film thickness of a thin film of titanium is 0.03 μm or greater and 0.2 μm or less and an average film thickness of a thin layer of copper is 0.5 μm or greater and 2 μm or less.

Then, a resist pattern is formed on a first thick layer by photolithography and a second thick layer of copper is formed by using electrolytic copper plating. Herein, an average film thickness of each of a first thick layer and second thick layer of copper is, for example, 20 μm or greater and 50 μm or less.

Then, a resist pattern is eliminated and etching is executed. Herein, a concentration of an etching liquid that is used for etching and a period of time to execute such etching are adjusted appropriately, so that it is possible to form a cut part with any shape where a third site of a resin layer is located. Subsequently, as a resin layer is formed by a paste for resin layer, printing is executed in such a manner that such a paste for resin layer penetrates into an inside of a cut part of a conductor layer, so that such a resin layer is of a shape that has a third site.

Additionally, after a first thick layer of copper is formed, a new resist pattern is formed without eliminating a resist pattern, and after a second thick layer of copper is formed, such a resist pattern may be eliminated.

Furthermore, although a conductor layer is fabricated in two batches in an explanation as described above, such a conductor layer may be fabricated in three or more batches to form a plurality of third sites in a direction of a thickness of a resin layer.

Furthermore, in a case where a number of a metal particle(s) in a first region of a resin layer is greater than that in a second region thereof, it is sufficient that two kinds of pastes for resin layer where numbers of an added metal particle(s) are different are prepared, and after a paste for resin layer with a smaller number of a metal particle(s) is printed previously, a paste for resin layer with a larger number of a metal particle(s) is printed thereon.

Then, a heat treatment is executed by holding at a maximum temperature of 140° C. or higher and 200° C. or lower for 0.5 hours or more and 3 hours or less.

Herein, in order that a conductor layer has a first site that covers at least a part of a site of a resin layer on a side of a conductor layer and a side of a surface of such a resin layer, it is sufficient that a metal such as copper that provides a first site is formed on a site of a paste for resin layer on a side of such a conductor layer and a side of a surface of such a paste for resin layer, by sputtering, electrolytic copper plating, or the like, after a heat treatment.

Alternatively, buffering that is a polishing process may be executed for a conductor layer and a surface of a resin layer to ductility-deform a surface of such a conductor layer and thereby form a first site. Herein, a feed rate, a count of an abrasive grain(s) to be used, and an amount of polishing that are a condition(s) of buffering are adjusted, so that it is possible to provide a first site of a conductor layer with any shape.

Thereby, a circuit board according to the present disclosure is obtained. Additionally, dicing may be executed to attain division into separate pieces, according to need. Additionally, in order to improve a reflectance or a corrosion resistance, plating with nickel-silver, silver, nickel-palladium-gold, nickel-gold, or the like may be executed on a conductor layer.

Then, it is possible to obtain a light-emitting device according to the present disclosure by, for example, mounting a light-emitting element on a circuit board according to the present disclosure.

### REFERENCE SIGNS LIST

1: substrate
2, 2a, 2b: conductor layer
3: resin layer
4: light-emitting element
5: bonding wire
10: circuit board
20: light-emitting device

1. A circuit board, comprising:
a substrate that is composed of a ceramic and has a first surface;
a conductor layer that is based on a metal; and
a resin layer that is based on a resin, wherein
each of the conductor layer and the resin layer is located side by side in contact with the first surface, and
the conductor layer has a first site that covers at least a part of a site of the resin later on a side of the conductor layer and a side of a surface of the resin layer.

2. The circuit board according to claim 1, wherein
a site that is away from the first surface in the first site is longer than a site that is close to the first surface, in terms of a length in a direction that is parallel to the first surface.

3. The circuit board according to claim 1, wherein
a maximum length of the first site in a direction that is parallel to the first surface is 3 μm or greater and 10 μm or less.

4. The circuit board according to claim 1, wherein
a maximum thickness of the first site in a direction that is orthogonal to the first surface is 3 μm or greater and 7 μm or less.

5. A circuit board, comprising:
a substrate that is composed of a ceramic and has a first surface;
a conductor layer that is based on a metal; and
a resin layer that is based on a resin, wherein
each of the conductor layer and the resin layer is located side by side in contact with the first surface,
the resin layer has a second site that protrudes toward a side of the conductor layer on a side of the first surface, and
the conductor layer covers at least a part of the second site.

6. The circuit board according to claim 5, wherein
a site of the second site that is close to the first surface is longer than a site that is away from the first surface, in terms of a length in a direction that is parallel to the first surface.

7. The circuit board according to claim 5, wherein
a maximum length of the second site in a direction that is parallel to the first surface is 4 μm or greater and 15 μm or less.

8. The circuit board according to claim 5, wherein
a maximum length of the second site in a direction that is orthogonal to the first surface is 3 μm or greater and 10 μm or less.

9. The circuit board according to claim 1, wherein
the resin layer has a second site that protrudes toward a side of the conductor layer on a side of the first surface, and
the conductor layer has a first site that covers at least a part of a site of the resin layer on a side of the conductor layer and a side of a surface of the resin layer, and covers at least a part of the second site.

10. The circuit board according to claim 1, wherein
the resin layer has a third site that protrudes toward the conductor layer, and
the conductor layer covers at least a part of the third site.

11. The circuit board according to claim 10, wherein
a site of the third site that is close to the first surface is longer than a site that is away from the first surface, in terms of a length in a direction that is parallel to the first surface.

12. The circuit board according to claim 1, wherein
the resin layer contains a metal particle(s) where an equivalent circle diameter(s) thereof is/are 5 μm or less, and
when a part of the resin layer that includes a surface in a direction away from the substrate is provided as a first region and a part other than the first region is provided as a second region, a number of the metal particle(s) in the first region is greater than that in the second region.

13. A light-emitting device, comprising:
the circuit board according to claim 1; and
a light-emitting element that is located on the circuit board.

14. The circuit board according to claim 5, wherein
the resin layer has a second site that protrudes toward a side of the conductor layer on a side of the first surface, and
the conductor layer has a first site that covers at least a part of a site of the resin layer on a side of the conductor layer and a side of a surface of the resin layer, and covers at least a part of the second site.

15. The circuit board according to claim 5, wherein
the resin layer has a third site that protrudes toward the conductor layer, and
the conductor layer covers at least a part of the third site.

16. The circuit board according to claim 15, wherein
a site of the third site that is close to the first surface is longer than a site that is away from the first surface, in terms of a length in a direction that is parallel to the first surface.

17. The circuit board according to claim 5, wherein
the resin layer contains a metal particle(s) where an equivalent circle diameter(s) thereof is/are 5 μm or less, and
when a part of the resin layer that includes a surface in a direction away from the substrate is provided as a first region and a part other than the first region is provided as a second region, a number of the metal particle(s) in the first region is greater than that in the second region.

18. A light-emitting device, comprising:
the circuit board according to claim 5; and
a light-emitting element that is located on the circuit board.
